(19) United States
(12) Patent Application Publication
(10) Pub. No.: US 2025/0109013 A1
(43) Pub. Date: Apr. 3, 2025

(54) CANTILEVER-BASED OPTO-ELECTROMECHANICAL SYSTEMS AND FABRICATION METHODS

(71) Applicant: City University of Hong Kong, Kowloon (HK)

(72) Inventors: Lixin Dong, Kowloon City (HK); Chaojian Hou, Kowloon City (HK); Kun Wang, Kowloon City (HK); Zhang Wenqi, Kowloon City (HK)

(21) Appl. No.: 18/480,260

(22) Filed: Oct. 3, 2023

(51) Int. Cl. B81C 1/00; H01J 37/26

(52) U.S. Cl. CPC B81C 1/0015; B81C 1/00531; H01J 37/26; H01J 2237/2007; H01J 2237/2802

(57) ABSTRACT

A system, multifunctional chip, and fabrication method thereof are provided. For example, a method for use in fabricating an opto-electromechanical system includes generating, from a film of a material and a substrate on which the film is disposed, a suspended portion of the film by removing a first portion of the substrate such that the film's first portion becomes the suspended portion and a second portion of the film is adjacent to a second portion of the substrate after removing the substrate's first portion. A two-dimensional nanomaterial is thereafter transferred onto a section of the suspended portion of the film via an all-dry process. A cantilever is thereafter generated from the film's suspended portion and extends from the film's second portion. The two-dimensional nanomaterial is disposed on the cantilever. Other aspects and features are also claimed and described.

### TECHNICAL FIELD

The present application relates generally to opto-electromechanical systems. More specifically, the present application relates to opto-electromechanical systems including a cantilever.

### BACKGROUND OF THE INVENTION

Nanorobotic manipulation of specimens can provide the capability of sub-nanometer positioning/deformation, pico-Newton-level force exertion/measurement, electromechanical engineering of functional elements, and robotic assembly for device prototyping. Together with the intervention of external physical fields (including mechanical, electrical, electromechanical, thermal, optical, magnetic fields, and liquid/gas environment), nanorobotic manipulation has enabled broader in-situ investigations of the dynamic behaviors of specimens at atom-level dynamic material intrinsic attributes (such as ion migration, dislocation evolution, phase transition, mechanical stress transformation and interlayer sliding). Such atom-level investigations, however, have been mainly focused on an atom-level evolution process to comprehensively understand the intrinsic attributes of materials and involve relatively simple devices with a few components.

Transmission electron microscopy (TEM) is a valuable characterization technology that offers static atom-level material intrinsic attributes (e.g., crystal structure, electronic topology, magnetic domain morphology, chemical composition, and structural biological information, etc.). Conventionally, the specimen preparation for in-situ TEM involves either in-situ or ex-situ electron beam induced deposition (EBID) for specimen fixing and electrode material deposition, focused ion beam (FIB) for specimen thinning or slicing, and a manipulator for specimen transferring. These processes and systems, however, are unsuitable for advanced-level-device fabrication. For instance, inadequate deposition material types and difficulty in achieving perfect material purity in EBID limit the Schottky barrier regulation at the interface between the metal electrode and the functional layer, greatly affecting the carrier extraction. Additionally, EBID typically ignores the effect of the contact quality (using a mobile probe to touch with the specimen) on the carrier transport properties in the common circuit configuration established inside TEM. In addition, the leakage current and carbon accumulation phenomenon of EBID directly impact device measurement accuracy. Moreover, the ion irradiation damage of specimens in the FIB process is not conducive to the protection of the device's functional layer. The time-consuming thinning process and complicated transferring process also increase the cost of device manufacturing.

A conventional transmission electron microscope (TEM) holder is also unsuitable for the measurement requirements under multi-physical coupling fields. Typical functional chips loaded on the TEM holder are used as a single external stimulus. A thermal chip only provides heat for the observation of atoms' dynamic evolution with temperature change. And a force chip only provides the driving force for atoms migration at the crystal interface. As such, in-situ TEM characterization under multi-physical coupling fields is limited in part by the complicated holder accessories. Integrating multifunctional micro-/nano semiconductor chips into in-situ TEM characterization platforms has been investigated for realizing in-situ device-level TEM characterization. There remains room for improvement, however, for typical technology and manufacturing processes related to in-situ device-level TEM characterization.

### BRIEF SUMMARY OF THE INVENTION

A new and innovative multifunctional chip and fabrication method thereof are provided. The multifunctional chip may be integrated with a sample holder of a TEM for the performance characterization of in-situ two-dimensional (2D) nanodevices. A provided in-situ opto-electromechanical TEM characterization sample holder reveals device performance and mechanism inside the TEM for in-situ device-level TEM characterization. Utilizing micro-fabrication technology and all-dry transfer technology of 2D nanomaterial, an ultra-flexible in-situ TEM multifunctional chip including a cantilever can be fabricated via a scalable and small-batch fabrication method. The provided multifunctional chip, fabrication method, and sample holder enable investigations that can provide strong support for the development of advanced in-situ device-level TEM characterization into the mechanism and application exploration of functional nanodevices, such as in-situ TEM force sensors, light sensors, and biosensors.

In an example, a method for use in fabricating an opto-electromechanical system includes generating, from a film of a material and a substrate on which the film is disposed, a suspended portion of the film by removing a first portion of the substrate that is adjacent to a first portion of the film prior to the first portion of the substrate being removed. The first portion of the film becomes the suspended portion after removing the first portion of the substrate, and a second portion of the film is adjacent to a second portion of the substrate after removing the first portion of the substrate. A two-dimensional nanomaterial is thereafter transferred onto a section of the suspended portion of the film via an all-dry transfer process. A cantilever is thereafter generated from the suspended portion of the film, wherein the cantilever extends from the second portion of the film. The cantilever includes the section onto which the two-dimensional nanomaterial is transferred such that the two-dimensional nanomaterial is disposed on the cantilever.

In another example, a method of constructing a sample holder of a transmission electron microscope includes fabricating a chip and integrating the chip with the sample holder. Fabricating the chip includes generating, from a film of a material and a substrate on which the film is disposed, a suspended portion of the film by removing a first portion of the substrate that is adjacent to a first portion of the film prior to the first portion of the substrate being removed. The first portion of the film becomes the suspended portion after removing the first portion of the substrate, and a second portion of the film is adjacent to a second portion of the substrate after removing the first portion of the substrate. A two-dimensional nanomaterial is thereafter transferred onto a section of the suspended portion of the film via an all-dry transfer process. A cantilever is thereafter generated from the suspended portion of the film, wherein the cantilever extends from the second portion of the film. The cantilever includes the section onto which the two-dimensional nanomaterial is transferred such that the two-dimensional nanomaterial is disposed on the cantilever.

In another example, an opto-electromechanical system includes a substrate and a film of a material. A first portion of the film is disposed on the substrate. The film comprises a cantilever that extends from the first portion of the film such that the cantilever extends away from the substrate. The system further includes a two-dimensional nanomaterial disposed on the cantilever.

Additional features and advantages of the disclosed method and apparatus are described in, and will be apparent from, the following Detailed Description and the Figures. The features and advantages described herein are not all-inclusive and, in particular, many additional features and advantages will be apparent to one of ordinary skill in the art in view of the figures and description. Moreover, it should be noted that the language used in the specification has been principally selected for readability and instructional purposes, and not to limit the scope of the inventive subject matter.

### BRIEF DESCRIPTION OF THE DRAWINGS

FIG. 1 illustrates a box diagram of an opto-electromechanical system, according to an aspect of the present disclosure.

FIG. 2 illustrates an example implementation of the opto-electromechanical system of FIG. 1 as a TEM sample holder, according to an aspect of the present disclosure.

FIG. 3(a) illustrates a perspective view of a sample stage of the TEM sample holder of FIG. 2 with the body of the sample stage shown transparent, according to an aspect of the present disclosure.

FIG. 3(b) illustrates a perspective view of a multifunctional chip, according to an aspect of the present disclosure.

FIG. 3(c) illustrates a magnified view of the multifunctional chip of FIG. 3(b), according to an aspect of the present disclosure.

FIG. 3(d) illustrates a magnified view of the loaded cantilever of the multifunctional chip of FIG. 3(c), according to an aspect of the present disclosure.

FIGS. 4(a)-(k) illustrate a fabrication method for the multifunctional chip of FIGS. 3(b)-(d), according to an aspect of the present disclosure.

FIG. 5 illustrates an example mask used in the fabrication method of FIGS. 4(a)-4(k), according to an aspect of the present disclosure.

FIGS. 6(a) and 6(b) illustrate a probe applying force to an example cantilever, according to an aspect of the present disclosure.

FIGS. 7(a)-(c) illustrate graphs showing relationships between z displacement of cantilever end and piezoresistive current, according to an aspect of the present disclosure.

FIGS. 8(a)-(c) illustrate graphs showing relationships between z displacement of cantilever end and piezoresistive current, according to an aspect of the present disclosure

FIGS. 9(a)-(f) illustrate graphs showing an opto-electromechanical coupling effect of the cantilever, according to an aspect of the present disclosure

### DETAILED DESCRIPTION OF THE INVENTION

The present disclosure provides a new and innovative opto-electromechanical system (e.g., platform) for in-situ device-level TEM characterization. The opto-electromechanical system may be coupled with mechanical, electrical, and optical fields. For the system to impactfully cooperate with the multi-physical fields, a new and innovative in-situ TEM multifunctional chip is also provided on which to load multifarious nanodevices. The multifunctional chip replaces conventional TEM chips, that are made of a surrounding fixed silicon nitride (Si₃N₄) thin film as a specimen supporting layer, with an ultra-flexible and ultra-thin cantilever design. The cantilever design offers a capacious working space and spatial geometric degrees of freedom, which allows making full use of the mechanical field by enabling the functional layer to have a large bending and torsion deformation.

The opto-electromechanical system, including the multifunctional chip and fabrication method thereof, further meets the basic TEM characterization requirements.

Specifically, the cantilever design offers sufficient physical field working space to obtain either a single physical field or multi-physical coupling fields. Additionally, the fabrication methods ensure that the as-fabricated TEM multifunctional chips are clean such that no carbon accumulation phenomenon appears inside the TEM. The opto-electromechanical system and multifunctional chip also enable the total thickness of the integrated device at the characterization site to satisfy TEM imaging requirements, and limit noise during device measurement to maintain device performance characterization accuracy. Based in part of these features, the opto-electromechanical system provides reliable support for the in-situ device-level TEM characterization, such as for flexible strain sensing and optoelectronic sensing.

The provided in-situ device-level TEM characterization technology relies on the atomic structure-device performance relationship instead of the conventional atomic structure-materials attributes relationship, which can aid in overcoming the barrier between material-level fundamental research and device-level application research. The multifunctional chips, when integrated inside a TEM, can establish a reliable device-level exploration link for the foundational science investigations combined with real-time atom-level imaging technology, including condensed matter physics, quantum physics, and so on. The integrated multifunctional chip can also aid in-situ TEM characterization systems in becoming more intelligent. The integrated multifunctional TEM chip can further be utilized as a sensing component (or a memory component) to respond to the external physical field (or record external environmental information), offering intelligent perception (or cognition) ability of in-situ TEM characterization systems to detect the change of physical quantities, chemical components, and biological information during the dynamic evolution processes. Specimen thickness matching with TEM imaging demand (about 100 nm thickness) is naturally compatible with a flexible membrane, supplying a precise performance calibration and in-depth mechanism investigation at the atomic level for flexible wearable devices. In addition, batch and high-quality TEM functional chip fabrication is feasible via mass-available micro-/nano semiconductor fabrication technology and large-area thin-film deposition or transferring technology. Such large-scale manufacturing greatly reduces the manufacturing difficulty and cost of the in-situ TEM functional chip.

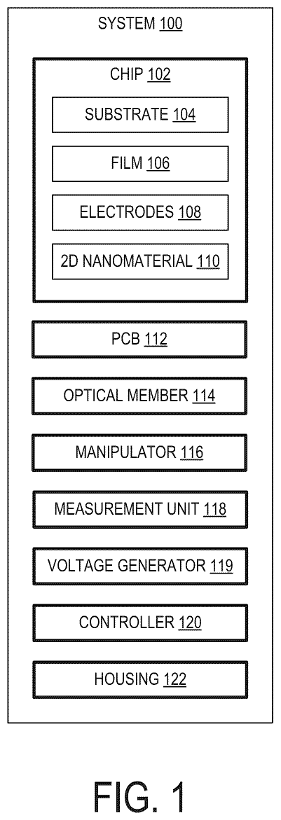

FIG. 1 is a block diagram of an example system 100, which may be an opto-electromechanical system. System 100 includes a multifunctional chip 102. Multifunctional chip 102 includes a substrate 104 and a thin film 106 of material disposed on substrate 104. Substrate 104 may include silicon or another suitable substrate material. In various examples, the material of thin film 106 may be silicon nitride (Si₃N₄), or other suitable materials as appreciated by one having skill in the art. In various examples, thin film 106 may have a thickness within a range of 200 to 500, 350 to 450, or 375 to 425 nanometers (nm), though these examples are not limiting. In one example, thin film 106 may have a thickness of 400 nm. A portion of thin film 106 forms a cantilever that extends away from the remaining portion of thin film 106 and substrate 104. Stated differently, no portion of substrate 104 is underneath the cantilever of thin film 106. Multifunctional chip 102 may further include a plurality of electrodes 108, for example, a source electrode and a drain electrode.

In at least some aspects, a 2D nanomaterial 108 is disposed on the cantilever of thin film 106. The 2D nanomaterial 108 may include one or more layers of material. In various aspects, a functional layer of 2D nanomaterial 108 may be molybdenum disulfide (MoS₂). System 100 further includes a printed circuit board (PCB) 112 electrically connected to multifunctional chip 102. In at least some aspects, an optical member 114 (e.g., optical fiber) is included with system 100. Optical member 114 may be connected to an optical source, such as a laser controller, such that optical member 114 can emit optical stimulus.

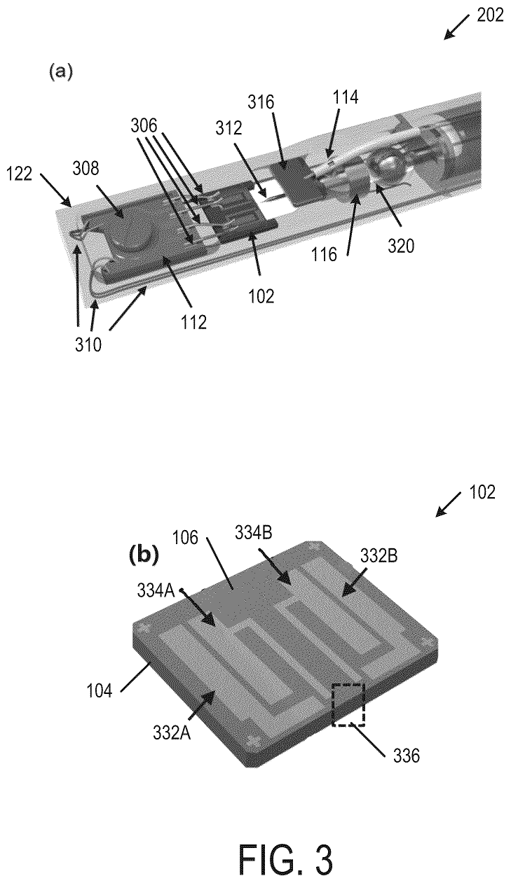

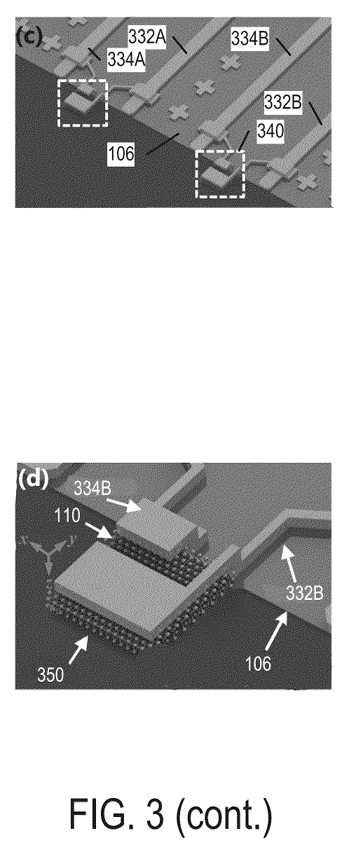

In various aspects, system 100 includes a manipulator 116 (e.g., nanomanipulator) that can effect mechanical stimulus on the cantilever portion of thin film 106 through a variety of deformation types, such as bending and twisting. FIGS. 6(a) and 6(b) each show an end-effector 312 (FIG. 3(a)) of manipulator 116 twisting a cantilever 350 (FIG. 3(d)) of thin film 106. Returning to FIG. 1, in some aspects, a step precision of manipulator 116 is at the sub-nanometer scale, which leads to ultrahigh-precision displacement and quantifiable stress tunability. Manipulator 116 may have three axes of movement in various aspects. In an example, manipulator 116 may include a probe that acts as an end-effector for in-situ tasks. In an example, manipulator 116 may be lead zirconate titanate (PZT)-driven.

To determine output signals, system 100 may include a measurement unit 118 (e.g., source meter), such as a 2-channel source measurement unit. System 100 may include a voltage generator 119 in various aspects. Voltage generator 119 may be controlled to generate high-voltage pulses. In at least some aspects, system 100 includes a controller 120 that controls various functions of the components of system 100, which in some instances, is in response to user inputs.

For example, controller 120 may control the movements of manipulator 116. In another example, controller 120 may receive output signals from measurement unit 118 and cause information associated with the output signals to be shown on a display. In another example, controller 120 may transmit signals to voltage generator 119 to cause voltage generator 119 to generate high-voltage pulses. Controller 120 includes one or more processors in communication with one or more memories storing processor-executable code. In some examples, at least one processor may execute all control functions for controller 120. In other examples, each processor executes only a portion of the control functions for controller 120. In some examples, at least one memory may store all of the processor executable code. In other examples, the processor executable code may be split among two or more memories. At least some of the components of system 100 may be integrated with, or disposed within, a housing 122.

Throughout the remaining figures, like reference numerals with FIG. 1 are used to indicate like components, but it should be appreciated that the remaining figures correspond to merely one example implementation of these components of system 100 in FIG. 1. In other examples, the components of system 100 may be implemented in different shapes and arrangements than the example implementation shown in the remaining figures.

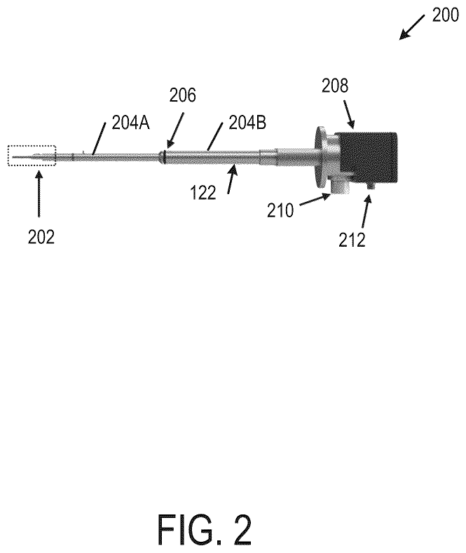

FIG. 2 is a perspective view of an example sample holder 200 of a TEM, which is an example implementation of system 100. In the illustrated example, housing 122 of sample holder 200 includes a first segment 204A and a second segment 204B. A vacuum seal 206 seals the point at which the first segment 204A meets the second segment 204B. For example, the first segment 204A may telescope within the second segment 204B. A sample stage 202 is integrated with housing 122 and will be described with more detail in connection with FIGS. 3(a)-(d). In various aspects, housing 122 includes a handle 208. Housing 122 may include a port 210. Port 210, in this example, is an electrical vacuum feedthrough so that electrical components of sample holder 200 may be electrically connected to components external to sample holder 200. Housing 122 may additionally or alternatively include a port 212. Port 212, in this example, is an optical vacuum feedthrough so that optical components (e.g., optical member 114) of sample holder 200 may be connected to components (e.g., laser controller) external to sample holder 200. For example, optical member 114 may be integrated into sample holder 200 through port 212.

FIGS. 3(a) and 3(b) show magnified views of sample stage 202 and multifunctional chip 102, respectively. Housing 122 of sample stage 202 is shown transparent. Sample stage 202 includes multifunctional chip 102. In the illustrated example, multifunctional chip 102 has an overall size that matches the TEM holder's card slot size. Multifunctional chip 102 includes thin film 106 disposed on substrate 104. In the illustrated example, electrodes 108 of multifunctional chip 102 constitute a peripheral lead-out circuit and include a first pair of source electrode 332A and drain electrode 334A and a second pair of source electrode 332B and drain electrode 334B. For instance, in this example, the two pairs enable two groups of in-situ devices each with one source terminal and one drain terminal. Stated differently, multifunctional chip 102 in this example is fabricated for a two-terminal nanodevice, with each pair being a terminal. In other examples, multifunctional chip 102 can be fabricated with a single pair of source and drain terminals or with more than two pairs.

Optical member 114 is introduced to sample stage 202 by a support member 316. In this way, optical member 114 may supply optical stimulus to multifunctional chip 102, and more specifically to a nanodevice disposed on multifunctional chip 102. Sample stage 202, in the illustrated example, further includes manipulator 116. Manipulator 116 includes an end-effector 312 (e.g., needle). In various aspects, end-effector 312 may be connected to manipulator 116 by a ball-cap pair 320. In at least some examples, end-effector 312 may include, or may be constructed from, tungsten (W). End-effector 312 may be utilized for performing mechanical in-situ tasks. By controlling (e.g., via controller 120) the position between end-effector 312 and 2D nanomaterial 210 disposed on the cantilever of thin film 106 of multifunctional chip 102, the cantilever can be deformed in a variety of ways (e.g., bending and twisting). In this way, end-effector 312 can operate as a reliable mechanical stimulus.

A plurality of metal contacts 306 (e.g., four in this example) correspond with electrodes 108 and thereby electrically connect multifunctional chip 102 with PCB 112. For example, each of the metal contacts 306 may be a pressing spring as illustrated in FIG. 3(a). By fastening a clamping bolt 308 on PCB 112, each of the metal contacts 306 implemented as pressing springs get a closed connection with one of source electrode 332A, drain electrode 334A, source electrode 332B or drain electrode 334B, respectively. A plurality of wires (e.g., five wires in this example) are included in housing 122 and lead out via port 212, with one wire connecting with the end-effector 312 and the other four wires connecting with the metal contacts 306 via PCB 112 so that electrical stimulus may be supplied to a nanodevice disposed on multifunctional chip 102.

As indicated by the dashed box in FIG. 3(b), multifunctional chip 102 includes an internal characterization circuit zone 336. FIG. 3(c) shows a magnified view of internal characterization circuit zone 336. As indicated by the dashed boxes in FIG. 3(c), internal characterization circuit zone 336 includes two loaded cantilever portions of thin film 106. FIG. 3(d) shows a magnified view of the components within the dashed box 340. A cantilever 350 of thin film 106 extends from the remaining portion of thin film 106 such that only one end of cantilever 350 is fixed to the remaining portion of thin film 106. The remaining sides (e.g. three sides in this example) of cantilever 350 are separate from, and free to move relative to, the remaining portion of thin film 106. Additionally, the remaining sides of cantilever 350 are not fixed (e.g., are separate from) to substrate 104, nor does cantilever 350 contact substrate 104. The completely released sides of cantilever 350 creates a free and vast operating space for manipulator 116, which enables a wide variety of deformation strategies (e.g., bending and twisting) of cantilever 350 and stress distribution (including symmetric or asymmetric tensile stress and compressive stress) of cantilever 350. Any of these deformation strategies and distress distributions can be achieved by changing the relative position (e.g., at the sub-nanometer scale) between end-effector 312 and cantilever 350. Cantilever 350 is shown loaded in FIG. 3(d) with multiple layers of 2D nanomaterial 110 disposed on the cantilever 350. Portions of source electrode 332B and drain electrode 334B are disposed on the top layer of 2D nanomaterial 110, which are electrically connected to the remaining portions of source electrode 332B and drain electrode 334B disposed on the remaining portion of thin film 106.

The source electrode 332B and drain electrode 334B are shaped in view of the mechanical strength of cantilever 350 and the circuit design. In this example, the source electrode 332B and a part of the drain electrode 334B cover a root segment of cantilever 350 at the interface between cantilever 350 and the remaining portion of thin film 106, which may serve as a strengthened plate to enhance the mechanical strength of cantilever 350. The “L” shape of the drain electrode 334B offers a large-area contact between the drain electrode 334B and function layer, which prevents high-frequency oscillation of cantilever 350 owing to the electron charging effect. Additionally, the electronic transmission path is along the shortest path of the channel via reasonable geometric dimensions. The carriers transport path is always along with the y-axis direction of multifunctional chip 102, which enables the bending deformation direction of 2y-axis direction of 2D nanomaterial to be consistent with the length of the channel. Such a design enables the mechanical force to naturally transfer into a functional layer at the center of the channel, steadily realizing the electromechanical coupling effect of the device. The opto-electronical and opto-electromechanical effects can be effected without or with dynamic deformation, respectively. In this way, by contrast with conventional TEM characterization systems for material attributes investigations, the provided opto-electromechanical TEM characterization system is designed for advanced in-situ device-level TEM characterization for the device mechanism and performance of functional nanodevices, such as sensors, photodetectors, memristors, etc.

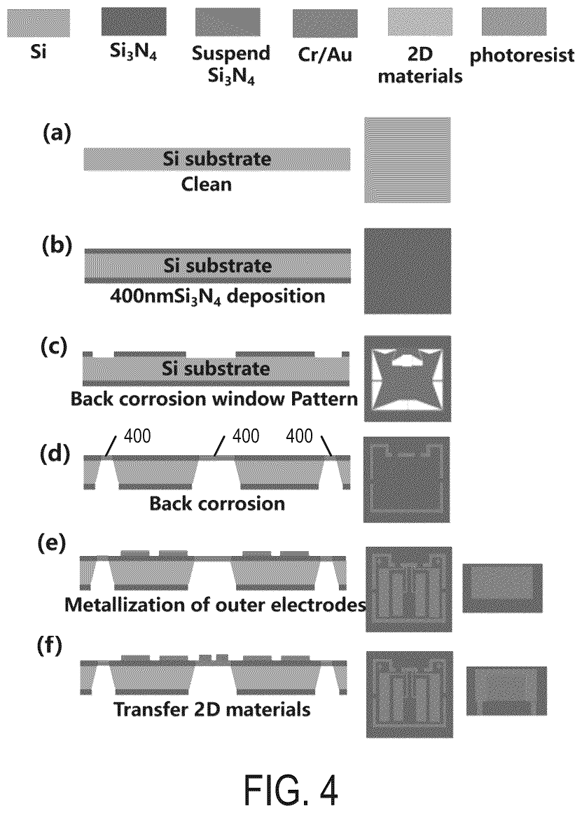

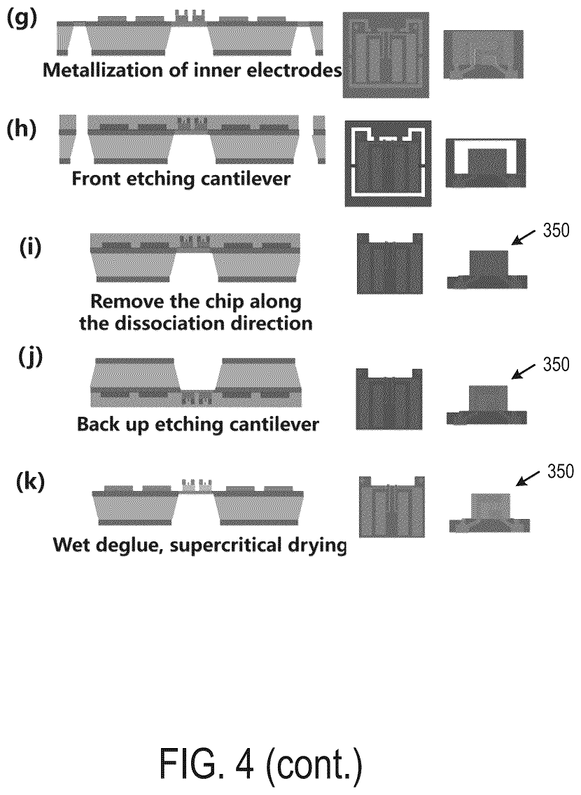

Fabrication of 2D nanomaterial 110 on cantilever 350 of thin film 106 necessitates cantilever 350 be ultrathin for matching ultra-high-resolution imaging requirements of TEM, the specimen surface to be clean for abstaining carbon accumulation phenomenon, and satisfying vacuum requirements. It is thus a technological challenge for realizing viable, reliable, repeatable, and batch fabrication of in-situ TEM multifunctional chip 102 having a cantilever 350. FIGS. 4(a) to 4(k) illustrate an example method for fabricating such a multifunctional chip 102. Each of FIGS. 4(a) to 4(k) illustrate a side view and a top view of multifunctional chip 102 through each of the fabrication stages. FIGS. 4(e) to 4(k) also illustrate magnified views showing the fabrication stages for fabricating cantilever 350. In FIG. 4(a), a silicon (Si) substrate 104 is cleaned, such as by soaking substrate 104 in acetone and deionized water and following with a nitrogen blowing. FIG. 4(a) also shows a legend that applies to each of FIGS. 4(a) to 4(k). In FIG. 4(b), a thin film 106 of silicon nitride (Si₃N₄) (e.g., a 2D nanoflake) is deposited on the clean Si substrate 104. For example, the Si₃N₄ thin-film 106 may be deposited via low-pressure chemical vapor deposition (LPCVD).

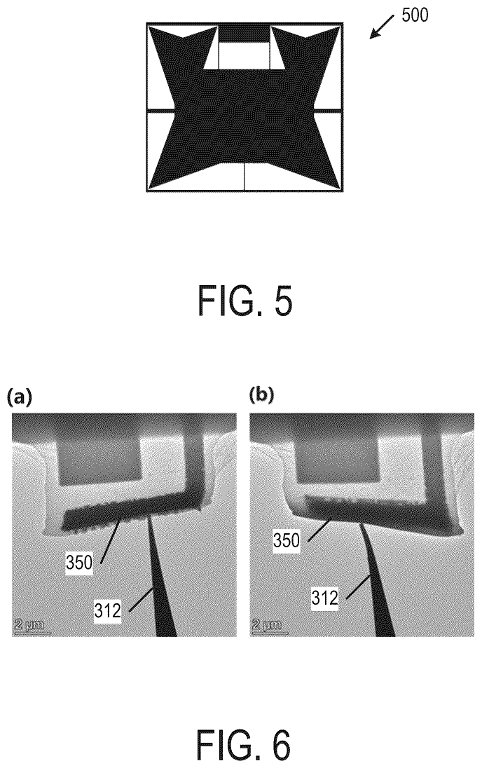

In FIG. 4(c), back corrosion window patterns are transferred onto the bottom surface of multifunctional chip 102, with the sides of the patterns along with the [110] crystal orientation, via ultraviolet lithography and reactive ion etching (RIE). FIG. 5 shows an example surface mask 500 for transferring the back corrosion window patters. Returning to FIG. 4(c), in this example, taking the anisotropic corrosion characteristics of the silicon substrate 104 into consideration, the main peripheral contour of the multifunctional chip 102 at every corner is compensated via a triangle with a side of the triangle along with the [210] crystal orientation. In various aspects, the line width of the suspended peripheral multifunctional chip 102 contour at the top surface of multifunctional chip 102 is 100 micrometers (m). In various aspects, the length and width of the Si₃N₄ film is 500 m and 100 m, respectively. The back pattern corresponding to surface mask 500 can be designed according to the relationship between the corrosion line width of the top and bottom surfaces of multifunctional chip 102.

A suspended portion of the thin film 106 may then be generated by removing a first portion of substrate 104 that is adjacent to a first portion of thin film 106 prior to the first portion of substrate 104 being removed. In this way, the first portion of thin film 106 becomes the suspended portion after removing the first portion of substrate 104. A second portion of the film is adjacent to a second portion of the substrate after removing the first portion of the substrate. For example, in FIG. 4(d), back wet corrosion (e.g., in a potassium hydroxide (KOH) solution) is carried out to remove a first portion of substrate 104 (comparing FIG. 4(d) to FIG. 4(c)) such that suspended portion 400 of Si₃N₄ thin film 106 is obtained. As illustrated in FIG. 4(d), suspended portion 400 is suspended in that the portion of Si substrate 104 adjacent to a first portion of Si₃N₄ thin film 106 is removed from beneath the first portion of Si₃N₄ thin film 106 such that the first portion becomes suspended portion 400. Batch-corrosion samples can be achieved in this way. Even though large amounts of gas concussions may be produced in the wet corrosion process, the mechanical strength of Si₃N₄ thin film 106 maintains the structure of suspended portions 400. The suspended portions 400 of Si₃N₄ thin film 106 can be divided into a peripheral contour zone and a cantilever fabrication zone.

In FIG. 4(e), portions of (e.g., outer portions of) source electrode 332A, drain electrode 334A, source electrode 332B and drain electrode 334B are metalized via ultraviolet lithography, development, thermal evaporation deposition, and lift-off. The suspended portion 400 of Si₃N₄ thin film 106 is then cleaned, such as by an oxygen plasma process with 100 watts (W) power and an O₂ flow rate of 120 cubic centimeters per minute (sccm) for about 3 min.

In FIG. 4(f), a 2D nanomaterial 110, which may include multiple layers, is transferred onto the suspended portion 400 of Si₃N₄ thin film 106 via an all-dry transfer process (e.g., no wet process is performed during the transfer process). In an example, the all-dry transfer process of mechanical-exfoliation 2D nanomaterial 110 is executed via polydimethylsiloxane (PDMS) glue fixed on a micro-manipulator under optical microscopy. The all-dry transfer process enables a transfer position of the 2D nanomaterial to be accurately attained onto the suspended portion 400 of the Si₃N₄ thin film 106. Additionally, by adjusting the rotation angle of the multifunctional chip 102, the crystal orientation of the 2D nanomaterial 110 can also be tuned with a precise angle, enabling the investigation of the effect of crystal orientation on the device's performance. Furthermore, the all-dry transfer process is time-efficient with only about ten minutes for each sample preparation. As such, combining large-area 2D nanomaterial 110 synthetization technology with large-area all-dry transfer technology is compatible with a batch semiconductor fabrication process.

In FIG. 4(g), the remaining portions of (e.g., inner portions of) source electrode 332A, drain electrode 334A, source electrode 332B and drain electrode 334B are fabricated onto the transferred 2D nanomaterial 110. For example, the inner portions may be fabricated via the same fabrication processes as the outer portions, except that the inner patterns may be obtained by e-beam lithography (EBL) due to the smallest electrode width at 1 μm. In FIG. 4(h), to achieve cantilever 350 of Si₃N₄ thin film 106, dry-etching with a photoresist protective mask may be utilized to penetrate the suspended portion 400 of Si₃N₄ thin film 106. Owing to the unetched support bridge at the left and right sides of the multifunctional chip 102, the entire multifunctional chip 102 can be stably suspended. In FIG. 4(i), to create an opened etching space, the suspended multifunctional chip 102 can be dissociated along the easiest dissociation direction [110].

In FIG. 4(j), the bottom surface of the multifunctional chip 102 is etched to reduce the thickness of cantilever 350. In various aspects, the final thickness of the suspended Si₃N₄-cantilever 350 is within the range of 100 to 180 nanometers (nm), inclusive of the ends of the range. In some aspects, the final thickness of the suspended Si₃N₄ cantilever 350 is less than 100 nm.

In FIG. 4(k), organic matter from the photoresist is removed at the surface of the multifunctional chip 102 to obtain a clean multifunctional chip 102 for abstaining carbon accumulation phenomenon and satisfying vacuum requirements. In an example, multifunctional chip 102 at this stage of the fabrication process may be successively emersed into isopropanol (IPA), acetone, and alcohol to remove the organic matter and its residue. In some aspects of this example, supercritical drying technology may be implemented to realize the final in-situ TEM multifunctional chip 102 with an ultra-flexible cantilever 350. Supercritical drying aids in reducing surface tension of cantilever 350 to reduce the likelihood of cantilever 350 collapsing due to surface tension. In some examples, for samples that are not susceptible to oxidation, soft oxygen plasma can be implemented as an additional process for the reduction of organics residue.

In this way, the fabrication process of FIGS. 4(a) to 4(k) provides a batch and reliable integration strategy, enabling realizing in-situ device-level TEM characterization of multifarious novel 2D nanodevices. Specifically, the adoption of micro-/nanofabrication technology into the sample preparation for in-situ characterization and experiments enables eliminating any dependence on the FIB method, providing more possibilities for material research and device construction. The all-dry transfer technology enables preparing the specimens with few-layer or even single-layer 2D nanomaterials while maintaining 2D structural properties. For instance, a graphene device with a single layer is difficult to achieve by conventional in-situ preparation methods due to the single layer being perpendicular to the electron path of TEM. Atomic precision deposition methods, such as magnetic sputter, e-beam deposition, thermal deposition, and atomic layer deposition, expand research on the type and structure of materials inside TEM. Additionally, the fabrication process's compatibility with micro-/nanofabrication technology enables cantilever 350 to be a powerful platform not only for in-situ device-level optoelectronics/opto-electromechanical research, but also for in-situ device-level ferroelectrics, electrochemistry, and other advanced characterizations. In addition, the access of abundant electrodes from the TEM holder and the in-situ multifunctional chip 102 further equips the multifunctional chip 102 with extra stimulation and testing capabilities for in-situ heating, mechanical measurements, or multi-terminal device construction.

Through the characterization of the in-situ multifunctional chip 102 under optical microscopy, scanning electron microscopy (SEM), and TEM, the inventors found that the bending angle of cantilever 350 was larger than 45°. Such large deformation can be applied to subsequent electromechanical characterization experiments. Additionally, the inventors found that the deformation of the cantilever 350 was still maintained after withdrawing end effector 312 by the manipulator 116, thus indicating that the plastic deformation appeared at low electron acceleration voltage at 10 kV e-beam acceleration voltage inside SEM. This phenomenon was distinguished from elastic deformation at 300 kV e-beam acceleration voltage inside TEM. In addition, the inventors did not find high-frequency oscillations phenomenon of the cantilever 350 nor carbon accumulation phenomenon, demonstrating that the cantilever 350 is compatible with the device measurements in the TEM environment.

Based on the in-situ TEM cantilever platform, the presence of piezoelectric or piezoresistive effects in MoS₂ nanoflakes enables in-situ probing into electromechanical coupling effect of the MoS₂ device accompanied by the deformation of the cantilever. Furthermore, strain-engineering modulation of the energy band structure (Femi lever E_{f} and bandgap E_{g}) of MoS₂ nanoflakes can offer an implementation mean for the investigation of the opto-electromechanical coupling effect of MoS₂ device. Associating the atom-level in-situ TEM imaging characterization with continuous and controllable modulation of the energy band structure of MoS₂ nanoflakes forms a brand-new analysis method for dynamic in-situ device-level TEM characterization.

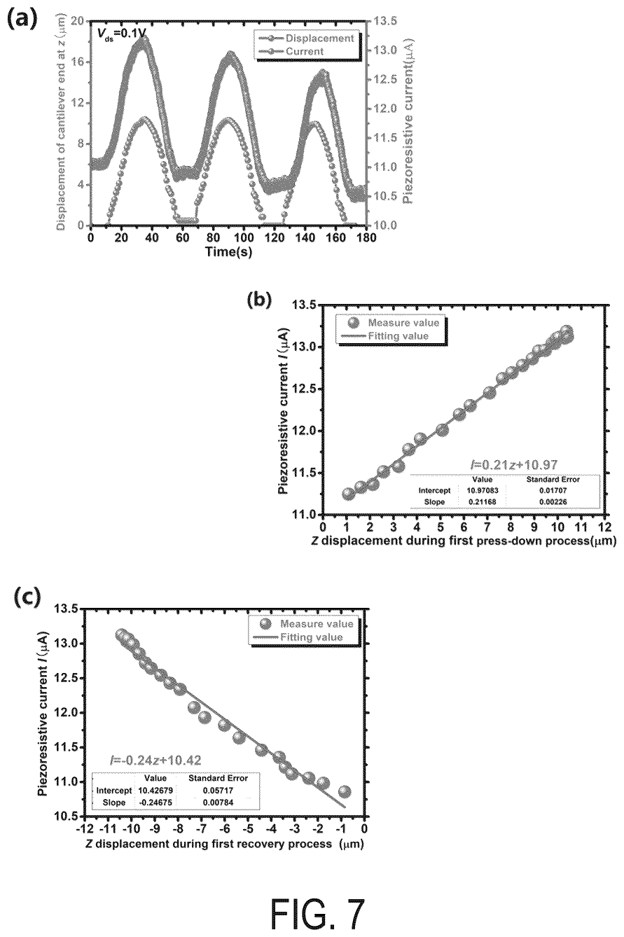

The tensile (compressive) strain of MoS₂ nanoflake can be easily acquired based on the multifunctional chip 102 via the press-down (lift-up process) of the cantilever, realized by adjusting z displacement of cantilever accompanied with W probe movement controlled by a high-precision nanomanipulator. FIG. 7(a) shows real-time z displacement of the cantilever end and piezoresistive current at a bias voltage of V_{ds}=0.1 V during three periodic press-down and recovery processes. Three repeated z displacement pulses and piezoresistive current pulses showed strong correlations over entire deformation processes, offering reliable proof for the electromechanical coupling effect in MoS₂ nanodevice. Specifically, once the W probe touched with a top layer of the cantilever, tensile strain occurred at the top layer of MoS₂ nanoflake between the source and drain terminal during the press-down process. With the gradual increase of z displacement of the cantilever, the tensile strain of the top layer of MoS₂ nanoflake increased. Such large tensile strain at the top layer of MoS₂ nanoflake directly increased I_{ds}. FIGS. 7(b) and 7(c) respectively show the relationships between piezoresistive current I_{ds} and z-direction displacement z during the first press-down process and the first recovery process of the first pulse in FIG. 7(a).

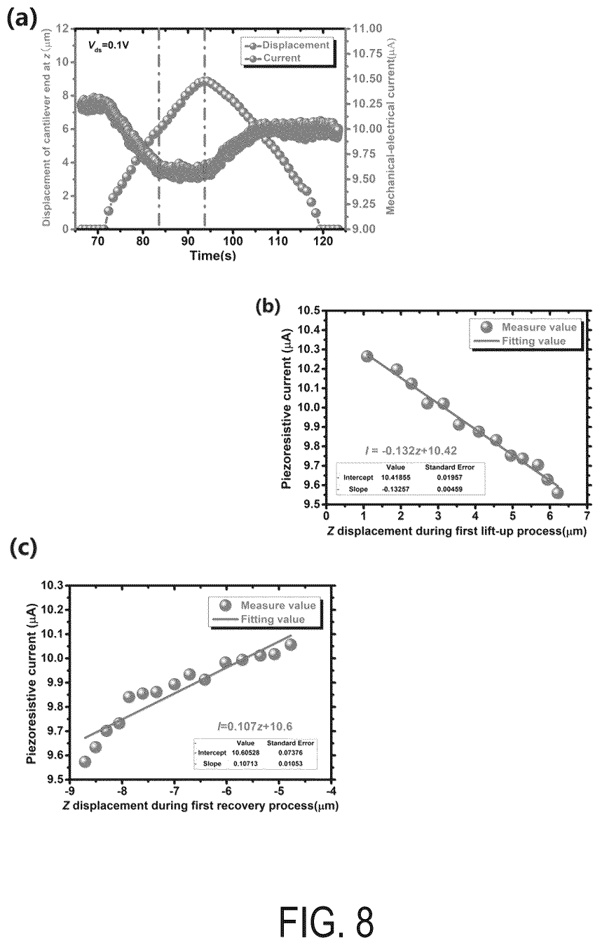

The compressive strain of MoS₂ nanoflake was also investigated based on multifunctional chip 102 via the lift-up process of the cantilever. The deformation morphology evolution during the entire process indicated that there was no obvious plastic deformation. FIG. 8(a) shows real-time z displacement of the cantilever end and piezoresistive current. FIGS. 8(b) and 8(c) respectively show relationships between piezoresistive current and z displacement from the linear zones of the maximum compressive strain during a lift-up process.

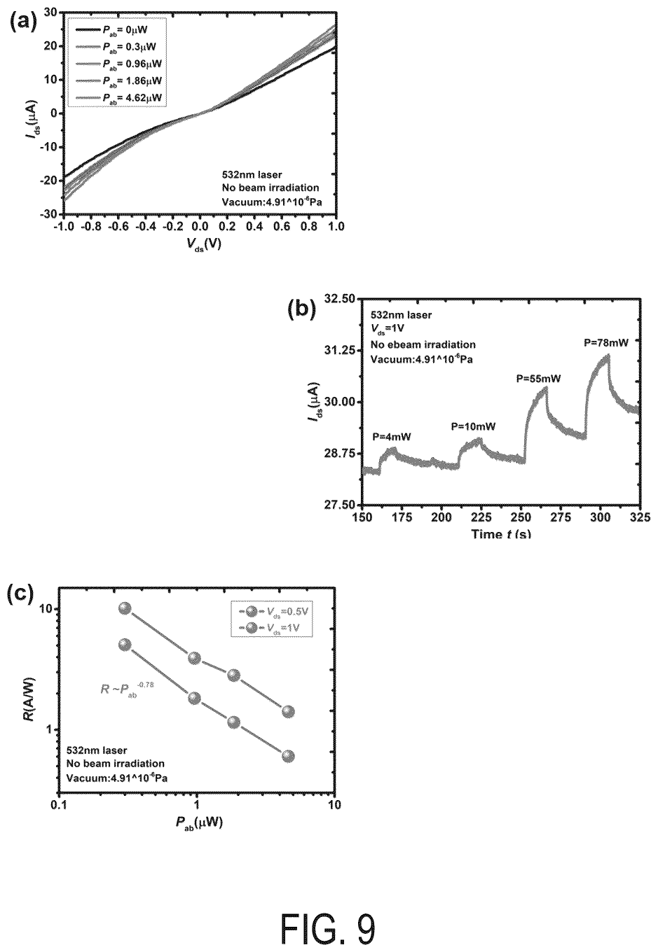

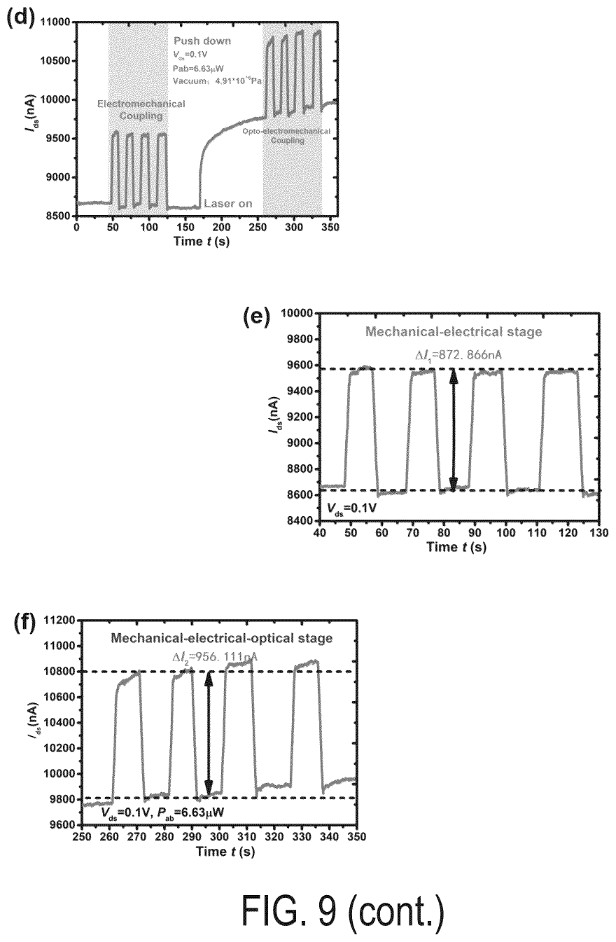

Before the opto-electromechanical characterization, the inventors first provided the detailed optoelectrical switching characteristic of ultra-flexible cantilever based on multilayer MoS₂ without e-beam irradiation and deformation, so that the device matches measurement requirement of opto-electromechanical coupling. FIG. 9(a) depicts the I_{ds}−V_{ds} output characteristics curve under different incident laser power. The output characteristics at P_{ab}=0 μW (in black) indicate the dark current level of a representative optoelectrical device on the ultra-flexible cantilever owing to the dark high vacuum space of TEM. This output characteristics exhibited slight nonlinearity and asymmetry, stemming from the asymmetric electrode structures. The dark current I_{ds} at the voltage of 1V and −1V are 19.90 μA and −18.88 μA. Such a large dark current was attributed to the thickness-dependent electron doping concentration. Generally, the thicker multilayer MoS₂ nanoflake, the higher n-type electron doping level, enabling a more electron concentration of MoS₂ nanoflake. The lower dark current also can be obtained by utilizing a thinner multilayer MoS₂ nanoflake. The wavelength of the incident laser is 532 nm. Remarkable enhancement of carrier transport was achieved, ascribing larger incident laser absorption power P_{ab} under the same bias voltage. Moreover, the change of output current I_{ds} under periodic laser on and off with gradually increasing the incident laser power P at the outlet of optical fiber was recorded to obtain the on-off switching characteristics of the device under laser stimulus.

FIG. 9(b) shows that each pulse exhibited rapid growth, following a slow current saturation trend. This phenomenon was attributed to the incident photon energy of the 532 nm laser much larger than the bandgap E_{g} of multilayer MoS₂ nanoflake, enabling a slow thermal relaxation effect. In addition, a longer recovery process of I_{ds} was also attributed to slow thermal relaxation. The conversion ability of light to current was characterized by photoresponsivity R, calculated by the Equation 1 below in which Iₚₕ, I_{ds}, and I₀ are the photocurrent, real-time recorded current, and dark current, respectively.

$$R = \frac{{I}_{ph}}{{P}_{ab}} = \frac{{I}_{ds} - {I}_{0}}{{P}_{ab}} \qquad ( 1 )$$

FIG. 9(c) shows the relationship between R and incident laser absorption power P_{ab} at both V_{ds}=0.5 V and V_{ds}=1 V. The maximum photoresponsivity is 10.15 A/W at V_{ds}=1 V and P_{ab}=0.3 μW. Moreover, as the laser power continuously increased, R continuously decreased regardless of the external bias voltage. This phenomenon was mainly attributed to Auger recombination or the saturation of the recombination trap state caused by high photon density, ultimately affecting the life of photocarriers and the reduction of photocarriers' concentration.

Based on the outstanding optoelectronic property of the above ultra-flexible cantilever based on multilayer MoS₂ nanoflake, both the electromechanical and opto-electromechanical coupling processes were carried out in an entire characterization during the press-down process of cantilever, as shown in FIG. 9(d). In the first stage from 40 s to 125 s, four repeatable pulses resulting from the piezoresistive effect belong to the electromechanical stage. At t=170 s, the optoelectrical coupling stage happened via laser on with the P_{ab}=6.63 μW and V_{ds}=0.1 V. After a long saturation stage, additional four groups of tensile strain were periodically loaded on the cantilever. By combining tensile strain with incident laser under suitable bias voltage, the opto-electromechanical coupling stage finally was formed, as shown in the light blue zone in FIG. 9(d).

To extract the contribution of opto-electromechanical coupling interaction to the current, FIG. 9(e) and FIG. 9(f) represent the I_{ds}−t curve at the electromechanical and opto-electromechanical coupling stages, respectively. The average current change amplitude ΔI₁ at the electromechanical coupling stage was 872.866 nA, while the average current change amplitude ΔI₂ at the opto-electromechanical coupling stage was 956.111 nA. Here, ΔI₁ represents the current variation contributed by the piezoresistive current during the bending deformation, but ΔI₂ represents the current variation contributed by both piezoresistive current and bending-induced photocurrent. Thus, bending-induced photocurrent A can be calculated by ΔI=Δ₂−Δ₁=83.245 nA.

As used herein, “about,” “approximately” and “substantially” are understood to refer to numbers in a range of numerals, for example the range of −10% to +10% of the referenced number, preferably −5% to +5% of the referenced number, more preferably −1% to +1% of the referenced number, most preferably −0.1% to +0.1% of the referenced number.

Furthermore, all numerical ranges herein should be understood to include all integers, whole or fractions, within the range. Moreover, these numerical ranges should be construed as providing support for a claim directed to any number or subset of numbers in that range. For example, a disclosure of from 1 to 10 should be construed as supporting a range of from 1 to 8, from 3 to 7, from 1 to 9, from 3.6 to 4.6, from 3.5 to 9.9, and so forth.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of the present application is not intended to be limited to the particular embodiments of the process, machine, manufacture, composition of matter, means, methods and steps described in the specification. The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

What is claimed is:

1. A method for use in fabricating an opto-electromechanical system comprising:
generating, from a film of a material and a substrate on which the film is disposed, a suspended portion of the film by removing a first portion of the substrate that is adjacent to a first portion of the film prior to the first portion of the substrate being removed, wherein the first portion of the film becomes the suspended portion after removing the first portion of the substrate, and wherein a second portion of the film is adjacent to a second portion of the substrate after removing the first portion of the substrate;
transferring a two-dimensional nanomaterial onto a section of the suspended portion of the film, wherein the transferring is an all-dry process; and
generating a cantilever from the suspended portion of the film, wherein the cantilever extends from the second portion of the film, and wherein the cantilever includes the section onto which the two-dimensional nanomaterial is transferred such that the two-dimensional nanomaterial is disposed on the cantilever.

2. The method of claim 1, wherein the material of the film is silicon nitride (Si₃N₄).

3. The method of claim 2, wherein a thickness of the second portion of the film is greater than a thickness of the cantilever of the film.

4. The method of claim 1, wherein the two-dimensional nanomaterial includes molybdenum disulfide (MoS₂).

5. The method of claim 1, wherein the two-dimensional nanomaterial includes a plurality of layers.

6. The method of claim 1, further comprising reducing a thickness of the cantilever.

7. The method of claim 1, further comprising metalizing a plurality of electrodes onto the two-dimensional nanomaterial prior to generating the cantilever.

8. The method of claim 1, wherein the all-dry process of transferring the two-dimensional nanomaterial onto the section of the suspended portion of the film is performed using polydimethylsiloxane (PDMS) glue.

9. The method of claim 1, further comprising drying the cantilever via a supercritical drying process.

10. The method of claim 1, wherein the opto-electromechanical system is configured for integration with a transmission electron microscope.

11. A method of constructing a sample holder of a transmission electron microscope, the method comprising:
fabricating a chip, which includes:
generating, from a film of a material and a substrate on which the film is disposed, a suspended portion of the film by removing a first portion of the substrate that is adjacent to a first portion of the film prior to the first portion of the substrate being removed, wherein the first portion of the film becomes the suspended portion after removing the first portion of the substrate, and wherein a second portion of the film is adjacent to a second portion of the substrate after removing the first portion of the substrate;
transferring a two-dimensional nanomaterial onto a section of the suspended portion of the film, wherein the transferring is an all-dry process; and
generating a cantilever from the suspended portion of the film, wherein the cantilever extends from the second portion of the film, and wherein the cantilever includes the section onto which the two-dimensional nanomaterial is transferred such that the two-dimensional nanomaterial is disposed on the cantilever; and
integrating the chip with the sample holder.

12. The method of claim 11, wherein the chip is integrated with a sample stage of the sample holder.

13. The method of claim 11, further comprising:
connecting the sample holder with a source of optical stimulus; and
connecting the sample holder with a source of electrical stimulus.

14. The method of claim 11, wherein the cantilever is generated using a photoresist mask.

15. An opto-electromechanical system comprising:
a substrate;
a film of a material, wherein a portion of the film is disposed on the substrate, and wherein the film comprises a cantilever that extends from the portion of the film such that the cantilever extends away from the substrate; and
a two-dimensional nanomaterial disposed on the cantilever.

16. The opto-electromechanical system of claim 15, wherein the material of the film is silicon nitride (Si₃N₄).

17. The opto-electromechanical system of claim 15, wherein the two-dimensional nanomaterial includes molybdenum disulfide (MoS₂).

18. The opto-electromechanical system of claim 15, wherein the two-dimensional nanomaterial includes a plurality of layers.

19. The opto-electromechanical system of claim 15, wherein the opto-electromechanical system is configured such that the opto-electromechanical system may be integrated with a transmission electron microscope.

20. The opto-electromechanical system of claim 15, further comprising a plurality of electrodes disposed on the two-dimensional nanomaterial.
